(19) United States
(12) Patent Application Publication
(10) Pub. No.: US 2013/0272324 A1
(43) Pub. Date: Oct. 17, 2013

(54) Monolithic Laser Cavity

(71) Applicant: ALFALIGHT, INC., Madison, WI (US)

(72) Inventors: Robert S. Williamson, III, Madison, WI (US); Yajun Lu, Sun Prairie, WI (US); David G. Barton, Madison, WI (US)

(21) Appl. No.: 13/861,201

(22) Filed: Apr. 11, 2013

Related U.S. Application Data
(60) Provisional application No. 61/622,595, filed on Apr. 11, 2012.

(51) Int. Cl. H01S 5/06

(52) U.S. Cl. CPC H01S 5/0604
USPC 372/22

(57) ABSTRACT

A monolithic laser cavity device includes an input mirror coating, a birefringent crystal quarter waveplate such as sapphire, a birefringent crystal gain medium such as neodymium-doped vanadate, a Type-II second-harmonic-generation crystal such as potassium titanyl phosphate, and an output mirror coating. The optical axes of the Type-II second-harmonic-generation crystal and birefringent crystal gain medium are aligned with each other and aligned 45° relative to the optical axis of the birefringent crystal quarter waveplate.

### CROSS-REFERENCE TO RELATED APPLICATIONS

This application claims priority from U.S. Provisional Patent Application 61/622595 filed Apr. 11, 2012, which is incorporated herein by reference.

### FIELD OF THE INVENTION

The present invention relates generally to a laser-diode pumped monolithic solid-state laser devices, and more particularly relates to an intracavity-doubled solid-state laser.

### BACKGROUND OF THE INVENTION

Solid-state lasers typically rely upon rare-earth-doped crystals to provide the gain element of the laser, and due to the nature of rare earth elements, typically produce invisible infrared radiation (oscillator). In order to produce a wider variety of laser wavelengths, in particular visible wavelengths, a non-linear optical element is introduced into the cavity to double, triple, or quadruple the oscillator frequency, producing a harmonic output wavelength. The non-linear element can be introduced external to the infrared oscillator, or internal to the oscillator, and can optionally be placed in a cavity that is resonant with the harmonic wavelength. These various configurations introduce tradeoffs of efficiency of harmonic generation from the oscillator wavelength, mechanical alignment tolerances of the optical elements, and requirements to control the temperature of the sensitive non-linear optical elements.

Because the efficiency of converting the oscillator to harmonic light is key to the operation of these cavities, high cavity finesse is required, often exceeding 100 and approaching 1000 for good conversion efficiency. This requires exceptionally high angular tolerances between the elements of the cavities to achieve these finesses levels. One means of achieving these angular tolerances are to use a monolithic laser cavity, which has been very successful for generating a wide range of visible wavelengths. In a monolithic cavity, the optical elements of the cavity are bonded together, either by the use of an intra-element adhesive, through intimate contact of the optical elements, or by external mechanical means.

In practice, cavities relying upon intra-element adhesives have limited finesse and sensitivity to operating temperature, leading therefore to limited harmonic generation efficiency, and limited ability to operate at high optical powers (which generate increased temperatures in the cavity assembly). Furthermore, adhesive-bearing cavities can have limited finesse due to optical absorption by the adhesive itself. Cavities that rely upon external mechanical means to hold alignment can be difficult and expensive to manufacture and also are intolerant of external mechanical and thermal stresses, leading to poor or variable performance.

Bonded cavities are thus often preferable for high-power and high-efficiency laser cavities. However, such cavities can suffer from limited operating temperature range due to mismatches in the coefficient of thermal expansion (CTE) of the materials in the cavity. Furthermore, the operating optical power level can be limited by CTE mismatch due to temperature rises within the cavity, most significantly from the gain medium which sustains high intrinsic losses in conversion from the pump laser light to the oscillator light.

Regardless of bonding means, any harmonic generation approach requires appropriate phase-matching between the oscillator and harmonic wavelengths. This is generally achieved by choosing the appropriate cut-angle of the extraordinary and ordinary axis, length of the second-harmonic generation crystal, and how the two laser spatial modes are focused and overlapped through the crystal.

One of the most common choices for low-cost, compact, and robust monolithic cavities is Type-II phase matching. In this configuration two oscillator beams whose polarizations are crossed 90° are mixed inside the non-linear crystal, specifically a second-harmonic generation (SHG) crystal. The two oscillator beams must maintain their crossed polarizations; if they are other than 90°, the efficiency of SHG drops dramatically, falling to 0% if the two polarizations are the same.

One of the most common configurations in the present state of the art is a neodymium-doped vanadate host crystal (Nd:YVO₄), which is a birefringent crystal and produces polarized 1064 nm light. This crystal is paired with a potassium titanyl phosphate (KTP) crystal cut at an angle to produce Type-II phase matching, and with its active optical axis crossed 45° from the vanadate crystal's axis. The vanadate and KTP are coated with mirrors that are highly reflective at 1064 nm to produce a high finesse cavity. The output is AR coated at 532 nm to allow the SHG light to escape from one or both ends of the cavity. In this configuration, due to the 45° crossing of the two crystals and the native birefringence of the vanadate, both forward- and reverse-propagating 1064 nm oscillator light end up at 90° and efficiently mixing in the KTP to produce SHG 532 nm light.

However, the birefringence of the vanadate crystal itself acts as an optical waveplate within the laser cavity, with a strong dependence upon the detailed thickness (optical path) of the vanadate crystal and the temperature of the crystal. If the vanadate crystal is the wrong thickness, or the temperature of the crystal changes (due to ambient conditions or to heat deposited in the crystal itself), the birefringence of the vanadate rotates the 1064 nm oscillator beam and reduces the efficiency of SHG conversion in the KTP crystal.

Because vanadate crystal boules can only be grown in small sizes (typically no more than 30 mm dia×40 mm), it is not cost-effective to polish the crystals to the submicron precision needed. In common production, they are assembled at low cost and tested and screened and binned for efficiency/output power. Very few are able to meet the tight thickness tolerances required for wide operating temperature.

Zhang et al. in U.S. Pat. No. 7,471,707 teaches the addition of a secondary compensation waveplate in the cavity, specifically an undoped YVO₄ waveplate acting to compensate the Nd:YVO₄ retardance, and a 0° alignment between the KTP and vanadate, to maintain a precise 90° relationship between the forward- and rear-propagating 1064 nm beams.

Ma et al, in Optics Express vol. 16 (2008), p.18702, teaches the addition of a secondary waveplate in the cavity, specifically an quartz quarter waveplate, and a 0° alignment between the KTP and vanadate, to maintain a precise 90° relationship between the forward- and rear-propagating 1064 nm beams. However, this choice of waveplate material places limits on the cavity construction due to a high CTE mismatch between the quartz and other elements of the cavity. Further, the different index of refraction of the quartz (˜1.5) from the other elements in the cavity (˜1.7 to ˜2.1) necessitates an optical anti-reflection (AR) coating on the surface, which adds cost and complicates many optical bonding techniques.

To summarize, the state-of-the art platform used to generate green laser light in excess of 5 mW and up to about 1000 mW is a frequency-doubled diode-pumped solid-state laser. This type of laser is typically fragile and has many precisely aligned parts, requiring it to be mechanically and thermally isolated by its packaging, leading to large parts and typically high power consumption. In all cases, these lasers will only function in ambient temperatures of 10-45° C. at most, and often require active cooling. Furthermore, the efficiency and/or output power decreases, sometimes irreversibly, when these lasers are operated in high or low temperature environments.

Monolithic or bonded laser cavities enable “alignment-free” manufacturing and much smaller overall laser sizes, but have historically been limited to 150 mW output power with 10-45° C. operating temperature range at best. The temperature range is limited by both the ability of the pump laser diode to maintain its wavelength over temperature and by the ability of the non-linear crystals to maintain their performance over temperature. Specifically, the optical elements in the cavity, notably the vanadate, change their birefringence over temperature, leading to decreased efficiency in conversion of infrared to green light at off-nominal operating temperatures.

### SUMMARY OF THE INVENTION

The current invention provides a monolithic laser cavity capable of providing efficient harmonic generation of laser output over a wide operating temperature range, over a wide optical output power range, and providing predictable manufacturing yields of said cavity. In embodiments of the invention, the cavity contains a gain medium, mirror, second harmonic generation crystal and birefringent crystal. The selection of the birefringent crystal material, orientation of optical axis, and location within the laser cavity uniquely enables robustness to changes in temperature and optical power. The unique design can be manufactured as a monolithic assembly affording low parts and assembly costs and resistance to environmental trauma such as mechanical vibration and shock and thermal shock.

Embodiments of the present invention provide a monolithic laser cavity containing a sapphire (or other suitable birefringent material), a waveplate (which provides a stable retardance inside the infrared laser cavity over temperature), and also provides a means for removing the heat from the laser cavity, both of which serve to improve the temperature performance. The particular embodiment described in this disclosure also uses a wavelength-stabilized pump laser diode to further enable the wide operating temperature of the pump plus laser cavity, but this is only one particular embodiment, and other embodiments need not include a wavelength-stabilized pump. The system disclosed in this invention provides over 500 mW of green laser light over an operating temperature range in excess of −30° C. to +65° C.

Following are some novel features and/or advantages of embodiments of the invention.
The operating temperature of monolithic crystal green lasers is significantly improved, from typically 10-35° C. to beyond −30 to +65° C.
The manufacturability and uniformity of the cavities from unit to unit is significantly improved; the L-I (light-current) curve of each cavity does not depend on difficult (or impossible) to control manufacturing variables such as the thickness of the vanadate crystal.
The L-I (light-current) curve of the cavity described in this invention is a better fit to a linear function than other monolithic SHG cavities (see figures); this enables precision control of power at any temperature within the operating temperature range for the cavity.
The output of the laser is controllable to very low output power; the current state-of the art is typically limited to a minimum of 30% of the cavity design power; the present invention can achieve less than 1% of the maximum design power
The laser described in this invention is able to achieve higher output power; output powers in excess of 700 mW have been demonstrated. This is achieved due to the superior thermal conductivity of the sapphire, enabling it to remove heat from the vanadate more efficiently than most other materials used in bonded laser cavities.
The invention allows for a truly monolithic and adhesive free bonding, which also enables high operating power and a wide operating temperature range.
The cost of the sapphire waveplate is not prohibitive in high volumes since the primary expense is wafer-level processing, not in the material or coating being applied.

The present invention provides a means of maintaining efficient second harmonic generation over a wide operating temperature, optical operating power, and enables predictable performance from unit to unit.

In contrast with the advantages of the present invention, following are limitations of previous approaches to achieve wide or improve temperature range or power range:
Use of crossed YVO₄ (vanadate) to cancel the Thermal Coefficient of Birefringence (TCOB)—this adds costs, does not fully solve the temperature range issue since the pairs of vanadate still vary in overall thickness, complicates optical pumping (due to variable cross-section).
Use of undoped YVO₄ to compensate the TCOB—this adds cost and is difficult to manufacture in volume because the small size of YVO₄ boules. High fundamental TCOB results in difficulty in volume manufacturing (small wafer size and requirement for very tight thickness tolerance).
Use of quartz as a compensating element. Compared to sapphire and YVO₄, quartz has a poor thermal conductivity, leading to limited heat removal and thus overall temperature range and output power capability. The TCOB of quartz is inferior to sapphire and requires tighter manufacturing tolerances. The CTE mismatch of quartz to the other cavity materials (YVO₄, KTP, and/or YAG) is significantly higher than the mismatch of sapphire's CTE.
Other approaches place a birefringent element elsewhere in the cavity, however, for high-power cavities (>150 mW) it is critical to isolate the input coating from the vanadate where a majority of the heat is deposited; only sapphire or similar material can provide high thermal conductivity, low TCOB, CTE match with surrounding materials, allow manufacturability with achievable tolerances in high volume, and provide mechanical isolation of the input coating from the hot YVO₄ pumped region.
Many other non-monolithic approaches also exist, but do not fall into the same class of solution because only a monolithic cavity approach can survive over very wide operating temperature and high shock/vibration environments. Non-monolithic approaches are fragile and require thermal stabilization, which significantly degrades the system power efficiency (wallplug efficiency).

### BRIEF DESCRIPTION OF THE DRAWINGS

FIG. 1 is a schematic cross-sectional view of an embodiment of the laser cavity showing a simple instantiation of the invention. The laser cavity itself contains an input mirror coating 102, a sapphire quarter waveplate 103, a gain medium, in this case Nd:YVO₄ 104, a Type-II SHG crystal, in this case KTP 105, and an output mirror/coupler 106. The laser cavity is pumped from the left-hand side with pump laser light 101. The second-harmonic generated light, in this case 532 nm, exits to the right 107.

FIG. 2 is a schematic cross-sectional view of an embodiment of the laser cavity shows a slightly different instantiation of the invention. It introduces to the cavity a new element 108, an undoped YAG interposer that serves to match the CTE of the Nd:YVO₄ 104 and the KTP 105, and also to reduce Fresnel losses at that same interface.

FIG. 3 is a schematic cross-sectional view of an embodiment of the laser cavity shows an instantiation of the invention with an embedded coating on the input of the KTP, which reflects the green (or other SHG beam) directly out of the KTP, improving the beam quality of the cavity's output.

FIG. 4 is a graph of green output versus pump current performance (L-I) for present invention (green) and previous state of the art (blue); shows the highly linear and predictable L-I performance from the present invention, compared to current state of the art. The high linearity results from stable birefringence in the cavity resulting in efficient green generation at all temperature and power levels.

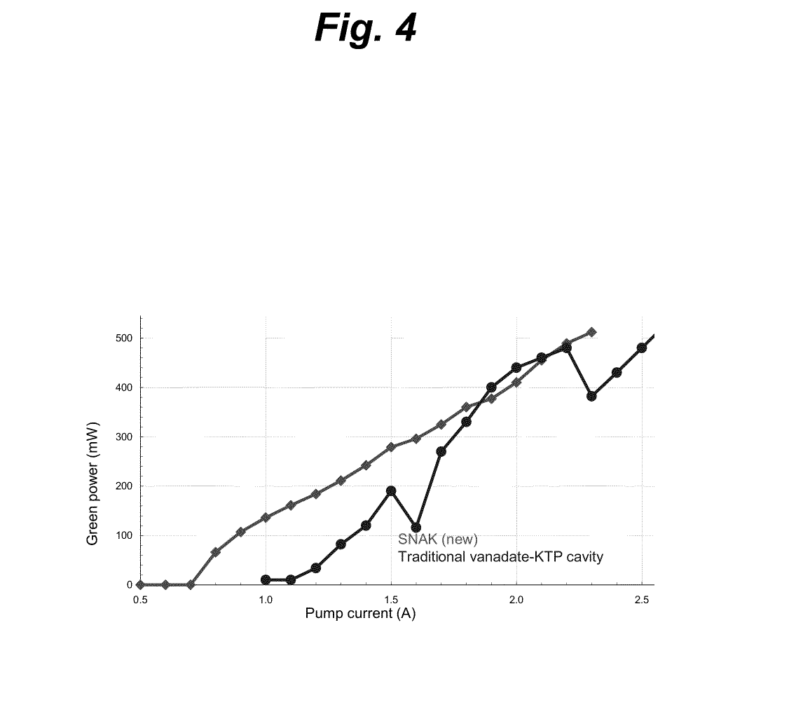

FIG. 5 is a graph of green output versus pump current performance (L-I) for 11 units showing uniformity of performance from unit to unit; shows the green output for 11 units versus pump drive current showing the uniformity of output from unit to unit. The units shown in this plot are all laser cavities as shown in the embodiment in FIG. 2, packaged with wavelength-stabilized pump diodes in a green laser package (shown in FIGS. 9 & 10).

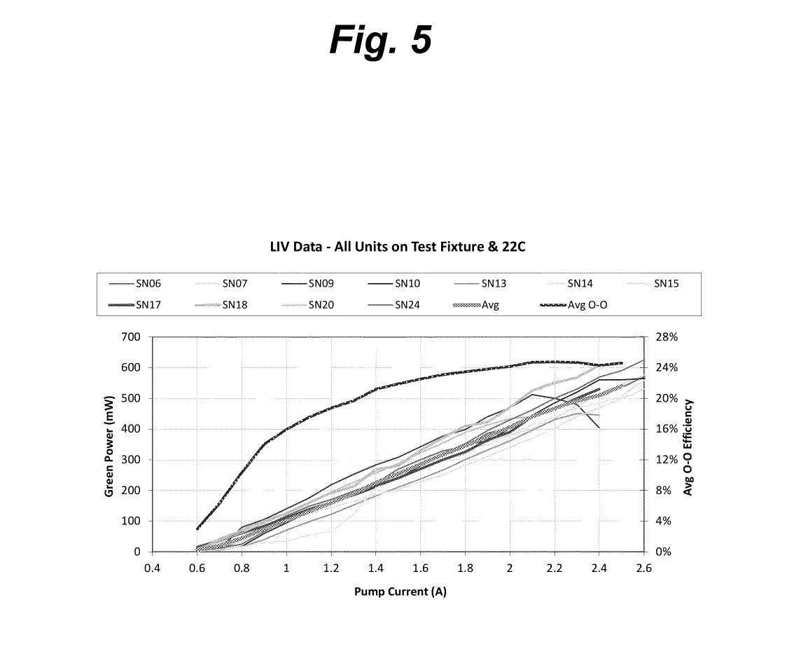

FIG. 6 is a graph of output of NLOD-2 units containing an embodiment of the laser cavities showing stable optical power performance over temperature. The output power is actively controlled to stay at 330 mW with a sampling photodiode and microcontroller adjusting the pump power.

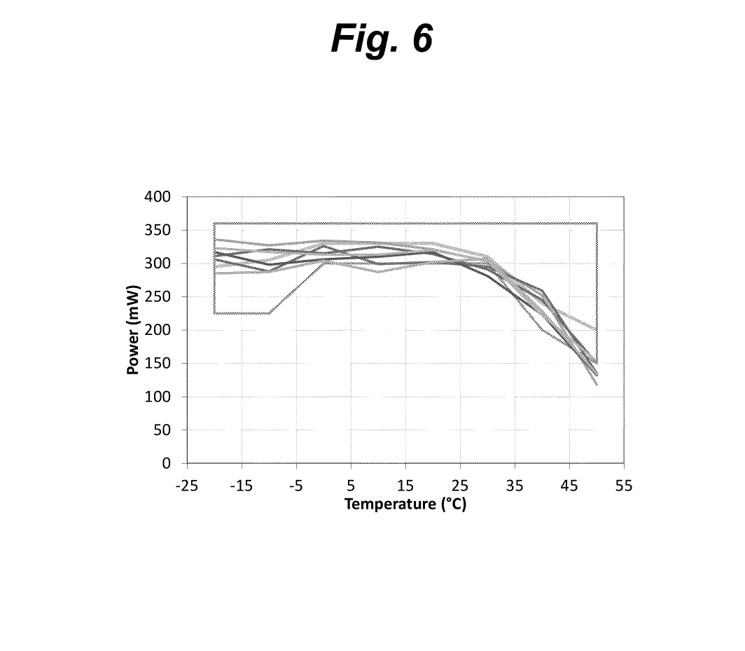

FIG. 7 is a graph of tolerance analysis of sapphire waveplate retardance over temperature, and for two thicknesses of sapphire quarter waveplate.

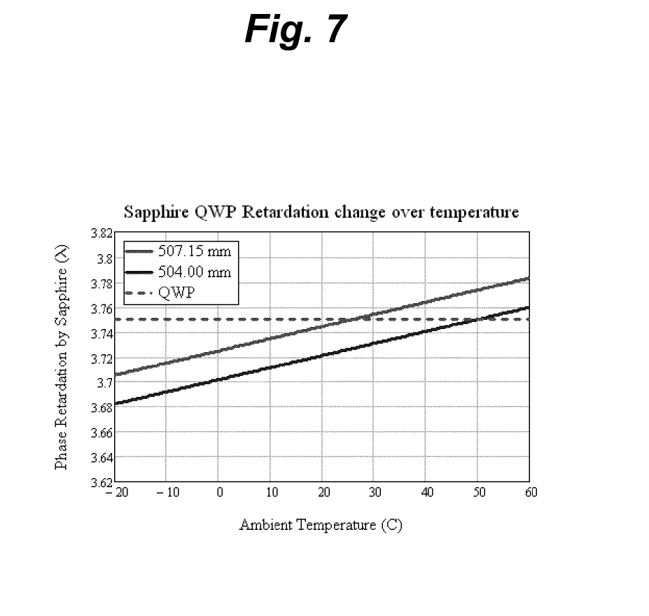

FIG. 8 is a graph of analysis of overall system performance for various tolerances including error in waveplate retardation and angular alignment error in assembly of cavity. “g-factor” us a measure of the SHG efficiency of the overall cavity, which stays above 90% for all tolerances examined in this plot. This plot was the result of a Jones matrix analysis that includes the retardance of all elements in the cavity.

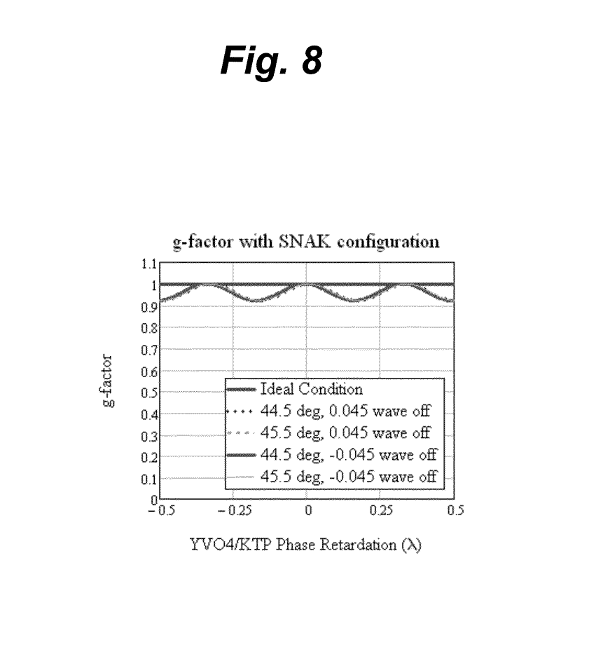

FIG. 9 is a cross-sectional view of a crystal implemented in a “green laser package” (GLP) according to an embodiment of the invention.

### DETAILED DESCRIPTION

It must be noted that as used herein and in the appended documents, the singular forms “a”, “an”, and “the” include plural reference unless the context clearly dictates otherwise. As well, the terms “a” (or “an”), “one or more” and “at least one” can be used interchangeably herein. It is also to be noted that the terms “comprising”, “including”, “characterized by” and “having” can be used interchangeably. All wavelengths are given in units of nanometers unless otherwise noted.

Unless defined otherwise, all technical and scientific terms used herein have the same meanings as commonly understood by one of ordinary skill in the art to which this invention belongs. All publications and patents specifically mentioned herein are incorporated by reference for all purposes including describing and disclosing the chemicals, instruments, statistical analyses and methodologies which are reported in the publications which might be used in connection with the invention. All references cited in this specification are to be taken as indicative of the level of skill in the art. Nothing herein is to be construed as an admission that the invention is not entitled to antedate such disclosure by virtue of prior invention.

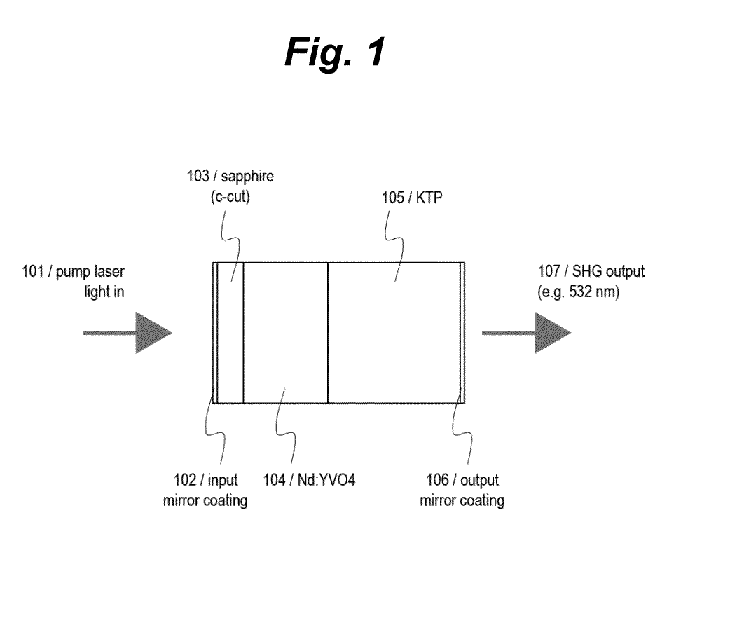

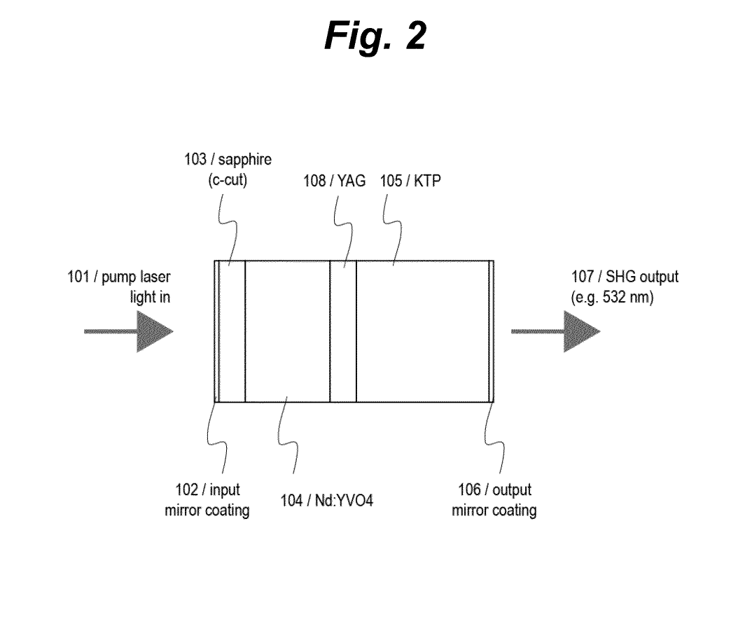

Embodiments of the invention are illustrated in FIGS. 1-3, where the following reference numerals are used.
101 Pump laser light in
102 Input mirror coating (AR 808, HR 532, VHR 1064)
103 Sapphire waveplate
104 Nd-doped vanadate (YVO₄)
105 KTP (potassium titanyl phosphate)
106 output mirror coating (AR 532, VHR 1064)
107 SHG output (532 nm green)
108 YAG (yttrium-aluminum-garnet)
109 Embedded coating (VAR 1064, HR 532)
201 Laser diode pump
202 Pump focusing lenses
203 Infrared pump beam
204 Green laser beam
205 Monitor photodiode
206 IR blocking filters
207 Reflective mirror
208 Sampling pickoff glass/IR blocking filter

In one embodiment, shown in FIG. 1, the cavity includes an input mirror or optical coating, a sapphire quarter-waveplate (at 1064 nm), the neodymium-doped vanadate gain crystal, the KTP SHG crystal, and an output coating. The optical axes of the KTP and Nd:YVO₄ are aligned, while the waveplate is rotated 45°. The thickness (and therefore order) of the sapphire waveplate is precisely selected to minimize the change of the retardation of the waveplate with temperature. At all operating temperatures, the waveplate precisely rotates the polarization of the forward- and backward-propagating beams, maintaining a 90° relationship. The input mirror is highly reflective (HR) at 1064 nm, reflective at 532 nm, and transmissive at 808 nm. The output mirror is HR at 1064 nm and transmissive at 532 nm.

The choice of sapphire for the waveplate material serves many purposes that are both unique and unexpected improvements over the use of quartz or other waveplate material:

a. The thermal conductivity of sapphire is high (˜30 W/m·K) and thus serves to lower the temperature of the vanadate or other gain medium it is adjacent to.

b. The index of refraction of sapphire is close to that of YVO₄, significantly reducing optical Fresnel losses at the interface, improving overall cavity and SHG conversion efficiency.

c. The TCOB of sapphire is comparably low compared to other waveplate materials, including quartz. TCOB is the difference in the thermo-optic coefficients of the ordinary and extraordinary axes of the material (dnₑ/dT−dnₒ/dT=TCOB, where dnₑ/dT and dnₒ/dT, measured in K⁻¹). The constants nₑ and nₒ represent the extraordinary and ordinary indices of refraction of the material, and dnₑ/dT and dnₒ/dT are the thermo-optic coefficients, representing the change in the indices of refraction with temperature. TCOB is thus a measure of the change in the birefringence or retardance of the material with temperature.
d. The cost of sapphire over other materials is less consequential when manufactured in even modest volumes because the majority of the cost of manufacture lay in the polishing process, which can be done in bulk.
e. Sapphire has a high modulus of elasticity (also Young's modulus) and therefore deforms less than other optical crystals when optical coatings are applied; this is a benefit for maintaining mechanical stability over operating temperature. Furthermore, the presence of the sapphire as an interposer isolates the high stresses of the input mirror coating from the vanadate, reducing birefringence losses in the gain medium, and minimizing issues related to thermal deformation in the gain medium.
f. The coefficient of thermal expansion of sapphire (CTE) closely matches that of vanadate, minimizing internal stresses in the monolithic crystal assembly when it is exposed to a wide range of operating temperatures and operating power levels (minimizing the effects of deposited heat within the crystal assembly).

In another embodiment, the waveplate thickness (order) is chosen so that the sapphire is nearly 0 or ½-wave retardance at 532 nm, maintaining a high level of polarization of the green output. Specifically, by making this choice, the directly exiting green beam and the one that is reflected by the input mirror have the same polarization state and thus the output is highly polarized.

In another embodiment, the coating on the sapphire waveplate is a “dot coating” wherein a mask is used to limit the extent of the coating to reduce internal stresses in the waveplate and reduce mechanical deformation of the sapphire.

Other embodiments of this invention include the use of differing birefringent materials for the waveplate, including sapphire (Al₂O₃), quartz (SiO₂), undoped vanadate (YVO₄), undoped (GdVO₄), barium borate (BBO), lithium niobate (LiNbO₃), ADP, KDP, rutile (TiO₂), tellurium dioxide (TeO₂), calcite (CaCO₃), magnesium fluoride (MgF₂), lead molybdenate (PbMoO₄), zircon (ZrSiO₄), beryl (Be₃Al₂(SiO₃)₆), diamond, and tourmaline. Further embodiments include waveplates whose thickness enables zero- and higher-orders of retardance. Other choices of waveplate will enable the invention, but may sacrifice one or more of the benefits of sapphire that was previously described.

Other embodiments of this invention include the use of different birefringent gain media, including doped yttrium vanadate (YVO₄), gadolinium vanadate (GdVO₄) mixed Y:Vₓ/Gdₗ₋ₓ:O₄, yttrium lanthanum fluoride (YLF), silica glass, etc.

Other embodiments of this invention include the use of different appropriate dopants in the gain medium including neodymium (Nd), etc., and various levels of doping, including, but not limited to 0.1, 0.2, 0.25, 0.3, 0.35, 0.5, 1.0, 2.0, and 3.0% percent doping by atomic weight. Other dopants appropriate to use in diode-pumped solid state lasers such as erbium (Er), ytterbium (Yb), mixed ErYb, chromium (alexandrite medium), or titanium (sapphire medium).

Most generally, any second-harmonic generation cavity relying upon Type-II phase matching and intracavity doubling may benefit from this cavity design, wherein the sapphire or other quarter waveplate, placed at the end of the monolithic laser cavity, controls the temperature coefficient of birefringence.

Instances of this invention include the use of varying optical pumping means, including broad-area laser diodes and wavelength-stabilized laser diodes. Further instances include the use of multiple laser diodes at varying wavelengths (to improve operating temperature range) that may both be standard broad-area lasers (BALs) or wavelength-stabilized (WST), or including grating-stabilized as well as externally stabilized, such as with volume Bragg gratings (VBGs).

Other embodiments include having the sapphire bonded to the gain medium (for heat removal benefits) but the SHG element is not bonded and is instead aligned in free space. Another embodiment has the sapphire standing free of the gain medium.

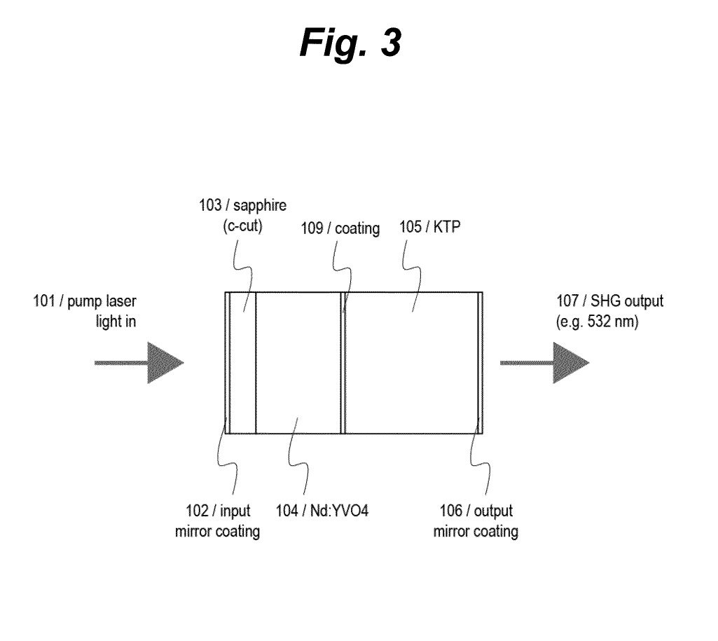

Another embodiment, shown in FIG. 3, has an embedded coating on the input of the KTP that is low-reflection at the infrared idler (1064 nm in this case) and HR at the SHG wavelength (532 nm). The benefits of this embodiment are that the SHG beam exits the KTP directly and this leads to the same polarization of SHG beam exiting, as well as improved beam quality owing to the two beam waist locations having better overlap. This can have direct implications when fiber-coupling the output of the cavity, or in trying to achieve a tightly focused spot.

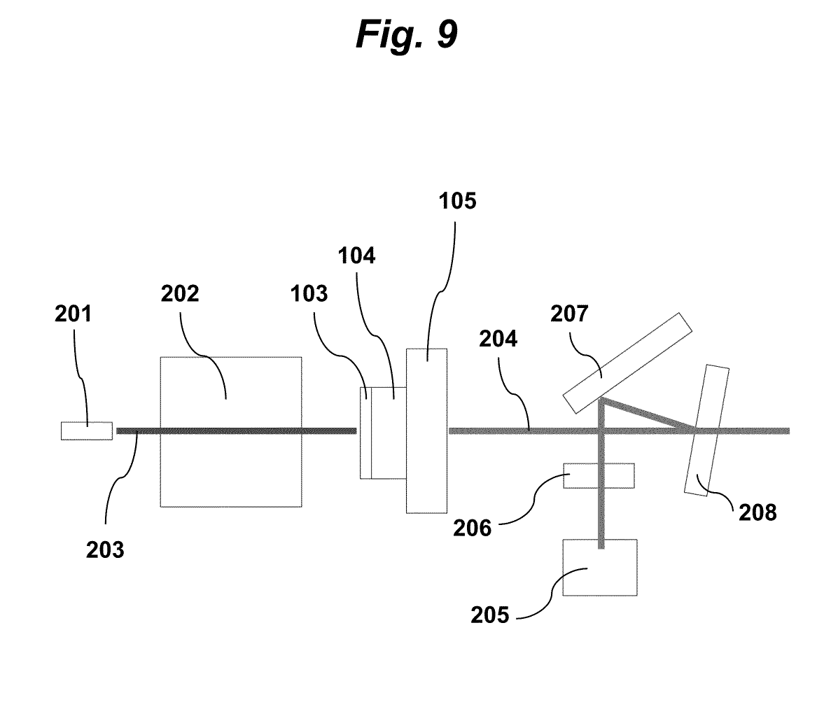

One embodiment of the crystal has been implemented in a full DPSSL, shown in FIG. 9 below. Unique aspects of that DPSS package include, but are not limited to:
Use of a WST (wavelength-stabilization technology) pump laser diode to enable wide operating temperature.
Active thermal management of the laser diode through controlled thermal interfaces, using an embedded thermistor and resistive heater. These are driven and controlled with a microcontroller and custom algorithm to enable deep cold operation with rapid turn-on and high efficiency for long battery life.
The use of active thermal management control circuitry that includes supercapacitors or ultracapacitors (defined as exceeding 0.5 Farad) to accelerate the rapid heating and minimizing turn-on time at cold temperatures.
Furthermore, the use of more than one heating element, one dedicated to discharging the supercapacitor efficiently.
Pump delivery optics including one or two elements, either aspherical or spherical. Pump delivery optics that include at least one cylindrical or acylindrical lens.
Mounting of the crystal for good thermal heat removal and survivability in a high shock and vibration environment. This mounting method may include a thermal interface solely on the sapphire waveplate or additional heat removal from the sides of the vanadate gain crystal.
Active optical pickoff using a custom method to ensure a high level of power control fidelity over a wide operating power range and a neutral density filter to limit the power to the photodiode and to prevent saturation. This includes a wedged, AR-coated pickoff to reduce interference effects and minimize loss and a mirror to reduce the pickoff angle of incidence while maintaining the overall compact pickoff package size. This further ensures that the optical power control functions well regardless of laser output polarization.
Integrated telescope to allow for precise setting of the output divergence of the device, as well as correct any X-Y steering errors; thus allowing every package to be nominally identical for easy downstream integration.
Active microcontroller-based power control architecture with optionally switchable transimpedance gain on the monitor photodiode that enables power control of the laser output power from 1 mW to over 700 mW with better than absolute 8% power stability.

While this invention has been described in conjunction with the various exemplary embodiments outlined above, various alternatives, modifications, variations, improvements and/or substantial equivalents, whether known or that may be presently unforeseen, may become apparent to those having at least ordinary skill in the art. Accordingly, the exemplary embodiments according to this invention, as set forth above, are intended to be illustrative not limiting. Various changes may be made without departing from the spirit and scope of the invention. Therefore, the invention is intended to embrace all known or later-developed alternatives, modifications, variations, improvements and/or substantial equivalents of these exemplary embodiments.

1. A monolithic laser cavity device comprising an input mirror coating, a birefringent crystal quarter waveplate, a birefringent crystal gain medium, a Type-II second-harmonic-generation crystal, and an output mirror coating.

2. The monolithic laser cavity device of claim 1 wherein the birefringent crystal quarter waveplate is a sapphire crystal.

3. The monolithic laser cavity device of claim 1 wherein the birefringent crystal gain medium is a neodymium-doped vanadate (Nd:YVO₄) crystal.

4. The monolithic laser cavity device of claim 1 wherein the Type-II second-harmonic-generation crystal is a potassium titanyl phosphate (KTP) crystal.

5. The monolithic laser cavity device of claim 1 wherein optical axes of the Type-II second-harmonic-generation crystal and birefringent crystal gain medium are aligned, while an optical axis of the birefringent crystal quarter waveplate is rotated 45° relative to the optical axes.

6. The monolithic laser cavity device of claim 1 further comprising an undoped YAG interposer that serves to match a coefficient of thermal expansion (CTE) of the birefringent crystal gain medium and the Type-II second-harmonic-generation crystal, and also to reduce Fresnel losses.

7. The monolithic laser cavity device of claim 1 further comprising an embedded coating on the input of the Type-II second-harmonic-generation crystal, wherein the embedded coating reflects a second-harmonic generation (SHG) beam directly out of the Type-II second-harmonic-generation crystal, improving an output beam quality of the cavity.
